(19) United States
(12) Patent Application Publication
(10) Pub. No.: US 2025/0258517 A1
(43) Pub. Date: Aug. 14, 2025

(54) CLOCK SIGNAL GENERATION

(71) Applicant: STMicroelectronics International N.V., Geneva (CH)

(72) Inventors: Fady ABOUZEID, La Terrasse (FR); Antoine ROUGET, Grenoble (FR); Adrian EVANS, Grenoble (FR); Vincent MENGUE, Grenoble (FR)

(73) Assignee: STMicroelectronics International N.V., Geneva (CH)

(21) Appl. No.: 19/038,503

(22) Filed: Jan. 27, 2025

(30) Foreign Application Priority Data
Feb. 12, 2024 (FR) FR2401337

(51) Int. Cl. G06F 1/08; G06F 1/12

(52) U.S. Cl. CPC G06F 1/08; G06F 1/12

(57) ABSTRACT

The present description concerns a method of generation of a first clock signal based on a second clock signal, the first and second clock signals having a same first period, and based on a third periodic signal having a second period equal to the first period divided by a number greater than or equal to two, the method comprising the following successive steps: counting a number of full periods of the third signal completed during a full period of the second clock signal; and generating the first clock signal by shifting the phase of the second clock signal by a delay equal to the second period multiplied by another number in the range from zero to the number.

### CROSS-REFERENCE TO RELATED APPLICATION(S)

This application claims the priority benefit of French patent application number FR2401337, filed on Feb. 12, 2024, entitled “Génération d'un signal d'horloge”, which is hereby incorporated by reference to the maximum extent allowable by law.

### BACKGROUND

### Technical Field

The present disclosure generally concerns electronic circuits and devices, and communications capable of being implemented between electronic circuits and devices. The present disclosure more specifically relates to the management of a communication between electronic devices using a plurality of communication channels synchronized by a same clock signal. The present disclosure concerns the management of such a clock signal.

### Description of the Related Art

There exist various ways enabling to transmit data between electronic devices. Data can be transmitted “serially” over the same communication channel, that is, one after the other. When a large amount of data is to be transmitted, it is common to use serializer/deserializer methods, which are energy-intensive, and may raise performance issues.

Another technique enabling to transfer a large amount of data between devices is to use a plurality of communication channels to transmit data “in parallel”, that is, all at the same time on different inputs and outputs. To differentiate data transmitted in parallel, it is important to ensure their synchronization with one or a plurality of different clock signals.

It would be desirable to be able to improve, at least partly, certain aspects of the management of a clock signal in a communication between electronic devices.

### BRIEF SUMMARY

There exists a use for higher-performance parallel data communications.

There exists a use for parallel data communications in which the data are better synchronized with one another.

There exists a use for parallel data communications in which a new clock signal is generated for data reception.

An embodiment overcomes all or part of the disadvantages of known parallel data communications.

An embodiment overcomes all or part of the disadvantages of known clock signal managements in parallel data communications.

An embodiment provides the use of a method of generation of a data reception clock signal, phase-shifted with respect to a clock signal transmitted with the data.

An embodiment provides the use of a circuit of generation of a data reception clock signal phase-shifted with respect to a clock signal transmitted with the data.

An embodiment provides a method of generation of a first clock signal based on a second clock signal, the first and second clock signals having a same first time period, and based on a third periodic signal having a second time period equal to said first time period divided by a first number greater than or equal to two, said method comprising the following successive steps: counting a second number of full periods of said third signal completed during a full period of said second clock signal; and generating said first clock signal by shifting the phase of said second clock signal by a delay equal to said second time period multiplied by a third number in the range from zero to said second number.

Another embodiment provides a circuit of generation of a first clock signal based on a second clock signal, the first and second clock signals having a same first time period, said circuit comprising:
an oscillating circuit adapted to generating a third signal having a second time period equal to said first time period divided by a first number greater than or equal to two;
a counter adapted to counting a second number of full periods of said third signal completed during a full period of said second clock signal; and
a delay circuit adapted to generating said first clock signal by shifting the phase of said second clock signal by a delay equal to said second time period multiplied by a third number in the range from zero to said second number.

According to an embodiment, said first number is greater than or equal to four.

According to an embodiment, said first number is greater than or equal to eight.

According to an embodiment, said third number is equal to said second number divided by a multiple of two.

According to an embodiment, said third number is equal to said second number divided by a multiple of four.

According to an embodiment, the counting of said second number is achieved by calculating an average of the number of full periods of said third signal which are completed during a plurality of full periods of said second clock signal.

According to an embodiment, to shift the phase of said second clock signal, a fourth signal changing state at each rising edge of said second clock signal and being delayed by said delay, and a fifth signal changing state at each falling edge of said second clock signal and being delayed by said delay, are used.

According to an embodiment, to obtain said first signal, a logic gate of “EXCLUSIVE OR” type is applied to said fourth signal and to said fifth signal.

According to an embodiment, the generation of said first clock signal is implemented by a delay circuit taking as an input said third number.

Another embodiment provides an electronic device comprising a previously-described circuit.

According to an embodiment, said circuit is included in a communication module of said device.

Another embodiment provides a method of communication between a first electronic device and a second electronic device.

According to an embodiment, said first clock signal is used to synchronize data signals received by said first device.

According to an embodiment, the communication method uses the single data rate protocol, the double data rate protocol, or the quad data rate protocol.

### BRIEF DESCRIPTION OF THE SEVERAL VIEWS OF THE DRAWINGS

The foregoing features and advantages, as well as others, will be described in detail in the rest of the disclosure of specific embodiments given as an illustration and not limitation with reference to the accompanying drawings, in which:

FIG. 1 shows, very schematically and in the form of blocks, an embodiment of a system capable of implementing the embodiments described hereafter;

FIG. 2 shows, very schematically and in the form of block diagrams, an embodiment of a clock signal generation circuit;

FIG. 3 shows a flowchart illustrating an implementation mode of a clock signal generation method;

FIG. 4 shows a practical example of the embodiment of FIG. 2;

FIG. 5 shows timing diagrams illustrating the operation of the circuit of FIG. 4; and

FIG. 6 shows another practical example of a portion of the embodiment of FIG. 2.

### DETAILED DESCRIPTION

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10%, preferably of plus or minus 5%.

The embodiments described hereafter concern the management of a clock signal, for example, during the implementation of a data communication between a plurality of devices, and, more particularly, the synchronization of data to a clock signal upon reception of these data by an electronic device. For this purpose, these embodiments provide the generation of a data reception clock signal shifted with respect to a clock signal transmitted with said data. This generation is described in detail in relation with FIGS. 2 to 5.

Further, the embodiments described hereafter are particularly adapted to electronic systems using parallel data communications, that is, communications comprising a plurality of communication channels transmitting different data. Such systems are, for example, electronic chips comprising a plurality of electronic components communicating with one another via such communications, such as application-specific integrated circuits (ASICs). These chips are for example intended for complex electronic systems, such as electronic systems used in motor vehicles or spacecrafts.

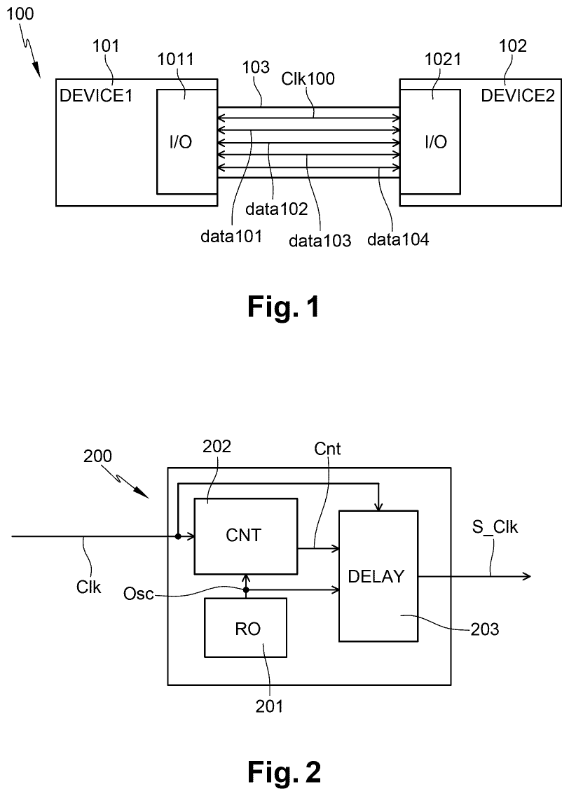

FIG. 1 shows, very schematically and in the form of blocks, an example of an electronic system 100 adapted to implementing the embodiments described in more detail in relation with FIGS. 2 to 5.

Electronic system 100 comprises at least two electronic devices 101 (DEVICE 1) and 102 (DEVICE 2) adapted to communicating with each other by using a communication device 103. Each device 101, respectively 102 comprises at least one communication module 1011 (I/O), respectively 1021 (I/O), enabling them to implement communication device 103.

According to an embodiment, communication device 103 enables to transfer data between devices 101 and 102 by using at least two communication channels. More particularly, device 103 comprises at least two communication channels, among which:
a first channel Clk100 adapted to transmitting a clock signal, called clock channel hereafter; and
one or a plurality of, preferably a plurality of, channels data101, data102, data103, data104, adapted to transmitting data, called data transmission channels hereafter.

There is here called, and throughout this description, “clock signal”, a periodic square-type digital signal. A clock signal is characterized by its frequency and its period, also called clock cycle. Its amplitude varies between a low level, generally corresponding to a “zero” or null level, and a high level, generally corresponding to a “one” level.

The clock signal transmitted by channel Clk100 is used to synchronize, or clock, the data signals transmitted by data transmission channel(s) data101 to data104.

Throughout this description, the term “data signal” is used to describe a digital signal having slots transmitting data, and being synchronized with a clock signal. Its amplitude varies between a low level, generally corresponding to a “zero” level or null level, and a high level, generally corresponding to a “one” level. The value of the amplitude of a data signal, during a clock cycle, represents the value of a data bit.

In the example illustrated in FIG. 1, device 103 comprises four data transmission channels data101, data102, data103, data104.

It should be noted that a device of the type of devices 101 can also send groups of data signals, each group using its own clock signal. The embodiments described hereafter can be adapted to such an operation.

A problem that may arise in a system of the type of system 100 is that it is possible for data signals received by a device to no longer be reliably synchronized with the clock signal transmitted via the clock channel. The embodiments described hereafter provide generating a reception clock signal to which it is certain that the data signals are correctly synchronized.

FIG. 2 shows, very schematically and in the form of blocks, an embodiment of a data reception clock signal generation circuit 200.

According to an embodiment, circuit 200 is adapted to receiving a data transmission clock signal Clk, that is, a clock signal transmitted with data, for example transmitted with a clock channel of the type of the channel Clk100 described in relation with FIG. 1. Clock signal Clk is used to synchronize data signals. Clock signal Clk has a clock frequency Folk and a period Tclk.

Circuit 200 is further adapted to supplying a data reception clock signal S_Clk which is a clock signal having data signals associated with clock signal Clk synchronized therewith. According to an embodiment, data reception clock signal S_Clk has the same clock frequency Folk as clock signal Clk. For example, clock signal Clk has a frequency in the range from 50 MHz to 10 GHz, preferably from 500 MHz to 2 GHz.

According to an embodiment within the abilities of those skilled in the art, data reception clock signal S_Clk has a frequency different from frequency Folk. More particularly, signal S_Clk has a frequency equal to a multiple of frequency Folk, such as, preferably, a frequency equal to twice or to half frequency Folk.

According to an embodiment, circuit 200 may form part of a communication module, of the type of the communication module 1011 or 1021 described in relation with FIG. 1, of a system of the type of the system 100 of FIG. 1.

Circuit 200 comprises an oscillating circuit 201 (RO) adapted to generating a signal Osc independently from clock signal Clk. Signal Osc is a periodic digital signal of square-wave type. Clock signal Osc has a frequency Fosc and a period Tosc. According to an embodiment, frequency Fosc is higher than clock frequency Folk. Similarly, according to an embodiment, period Tosc is shorter than clock cycle Tclk.

More particularly, period Tosc is given by the following mathematical formula:

$$Tosc = \frac{Tclk}{K} \qquad [ Math 1 ]$$

According to a preferred embodiment, K is a natural number greater than or equal to two. When number K is not an integer, circuit 200 operates with a jitter, which can be compensated for by a jitter correction circuit.

Circuit 200 further comprises a counter 202 (CNT) adapted to receiving clock signal Clk and signal Osc. Counter 202 is used to count the number of periods of signal Osc which have been completed during a clock cycle Tolk of clock signal Clk. For this purpose, the counter value is set to zero at the beginning of a clock cycle of clock signal Clk, and then incremented each time a full period of signal Osc is completed. Counter 202 delivers, as an output, its value cnt.

Circuit 200 further comprises a delay circuit 203 (DELAY) adapted to shifting the phase of clock signal Clk by a time delay D. According to an embodiment, delay circuit 203 is adapted to receiving clock signal Clk. According to an example, delay circuit 203 is adapted to further receiving value cnt and signal Osc. According to an embodiment, delay circuit 203 is adapted to delivering, as an output, reception clock signal S_Clk.

According to a first embodiment, the time delay D applied by the delay circuit is given by the following mathematical formula:

$$D = Tosc * P \qquad [ Math 2 ]$$

where P is a parameter defined by a user, preferably P is in the range from 1 to value cnt.

According to a second preferred embodiment, the time delay D applied by the delay circuit is given by the following mathematical formula, which defines parameter P in more detail:

$$D = Tosc * \frac{cnt}{2 * n} \qquad [ Math 3 ]$$

where n is a number, preferably an integer equal to:
one if the data signals synchronized to clock signal Clk follow a single data rate (SDR) protocol;
two if the data signals synchronized to clock signal Clk follow a double data rate (DDR) protocol;
four if the data signals synchronized to clock signal Clk follow a quad data rate (QDR) protocol.

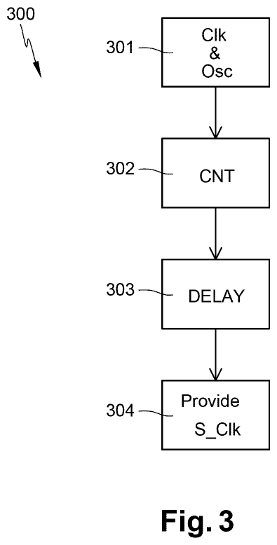

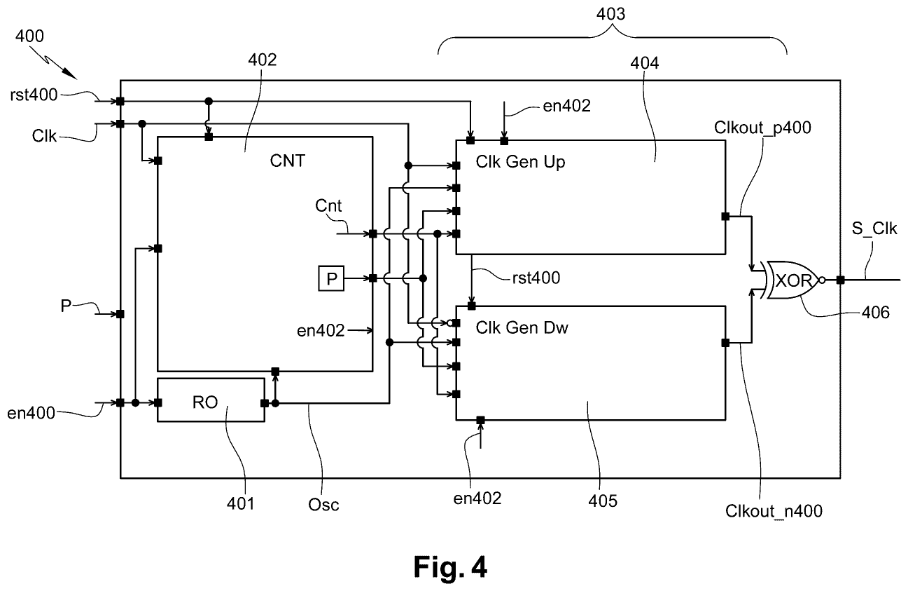

The operation and the advantages of circuit 200 are described in detail in relation with FIG. 3.

FIG. 3 is a block diagram illustrating the implementation of an implementation mode of a method 300 of generation of a data reception clock signal. More particularly, FIG. 3 illustrates the operation of the circuit 200 described in relation with FIG. 1.

In an initial step 301 (Clk & Osc), circuit 200 receives clock signal Clk. The oscillating circuit 201 of circuit 200 generates, or starts generating, signal Osc.

At a step 302 (CNT), successive to step 301, a counting step is implemented by counter 202. For this purpose, counter value cnt is set to zero at the beginning of a clock cycle of clock signal Clk, and is then incremented each time a full period of signal Osc ends. According to an example, it is considered that a period of clock signal Clk or of signal Osc starts at a rising edge, and ends at the next rising edge. In this case, counter value cnt is set to zero at a first rising edge of clock signal Clk, and then incremented each time signal Osc exhibits two consecutive rising edges. As a variant, it can be considered that a period of clock signal Clk or of signal Osc starts at a falling edge and ends at the next falling edge.

Step 302 ends when the clock cycle of clock signal Clk ends. The value cnt of counter 202 then represents the number of full periods of signal Osc which have occurred during a clock cycle of clock signal Clk. Value cnt is ready to be supplied to other circuits of device 200.

According to an alternative embodiment, the value cnt of the counter may also be calculated by taking an average over a plurality of clock cycles of signal Clk, of the number of full periods of signal Osc which have occurred. Value cnt may, in this case, not be an integer. Value cnt may, in a first embodiment, be rounded up, or, in a second embodiment, be rounded down. It is up to the user to choose what is most convenient, according to the communication protocols used.

At a step 303 (DELAY), successive to step 302, a new clock signal S_Clk corresponding to clock signal Clk delayed in time by the previously-defined delay D is generated by delay circuit 203. As a reminder, according to a first embodiment, delay D depends on parameter P, in the range from one to value cnt, and according to a second preferred embodiment, delay D depends on value cnt.

At a step 304 (Provide S_Clk), successive to step 303, clock signal Clk delayed by time delay D is equal to reception clock signal S_Clk. Signal S_Clk is thus output by delay circuit 203.

An advantage of this embodiment is that it enables to provide a data reception clock signal better synchronized with data signals received by an electronic device. Indeed, there may happen that a data transmission device unintentionally causes a desynchronization of data signals and of the clock signal which is associated therewith. This may enable to sample the data signals when they are stable, since this may involve an adjustment of the phase of clock signal S_CLK. This may also enable to overcome certain variabilities inherent to electronic component and device manufacturing methods.

To ensure the correct synchronization of data signals with the reception clock signal, the latter is shifted by a delay corresponding to the time of the clock cycle when a data item represented by a data signal is most stable, that is, the point equidistant between the data item of a cycle and the data item of the next cycle. This time differs according to the communication protocol used. P protocols are possible, such as single data rate, double data rate, and quad data rate.

In the case of the use of the single data rate protocol, a data signal exhibits one data bit during one clock cycle. The time when the value of the data bit transmitted by the signal is most stable is at the mid-period or in the middle of the clock cycle. It is thus advantageous to shift the reception clock signal by a time delay equivalent to approximately half a period. This time delay is estimated based on signal Osc as described hereabove.

In the case of the use of the double data rate protocol, a data signal exhibits two data bits during a clock cycle, a first bit during its “high” state and a second bit during its “low” state. The times when the values of these data bits transmitted by the signal are most stable are at the first quarter of the clock cycle and at the third quarter of the clock cycle. It is thus advantageous to shift the reception clock signal by a time delay equivalent to approximately one quarter of a period. This time delay is estimated based on signal Osc as described hereabove.

In the case of the use of the quad data rate protocol, a data signal exhibits four data bits during a clock cycle, a first bit during the transition from a “low” to a “high” state, a second bit during its high state, a third bit during the transition from a “high” to a “low” state, and a fourth bit during the low state. The times when the values of these data bits transmitted by the signal are the most stable are at the first eighth of the clock cycle, at the third eighth of the clock cycle, at the fifth eighth of the clock cycle, and at the seventh eighth of the clock cycle. It is thus advantageous to shift the reception clock signal by a time delay equivalent to approximately one eighth of a period. This time delay is estimated based on signal Osc, as described above.

According to an embodiment, such a method of generation of a data reception clock signal may be comprised in a communication method within a system of the type of the system 100 described in relation with FIG. 1.

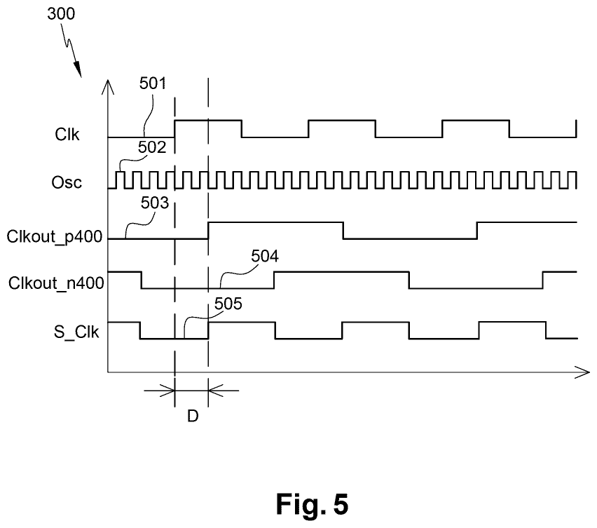

FIG. 4 shows, in the form of blocks, a practical example of an embodiment of a circuit 400 of generation of a data reception clock signal of the type of the circuit 200 described in relation with FIG. 1.

According to an example, circuit 400 receives:
clock signal Clk;
a reset signal rst400;
an enable signal en400; and a signal representing the previously-defined parameter P.

According to an embodiment, circuit 400 delivers, as an output, reception clock signal S_Clk.

Further, as previously described, circuit 400 comprises:
an oscillating circuit 401 (RO);
a counter 402 (CNT); and
a delay circuit 403.

Like oscillating circuit 201, oscillating circuit 401 is adapted to generating signal Osc, previously defined, independently from clock signal Clk. According to an example, oscillating circuit 401 is adapted to being started or enabled by enable signal en400.

Like counter 202, counter 402 is used to count the number of periods of signal Osc which have been completed during a clock cycle Telk of clock signal Clk. For this purpose, counter 402 receives clock signal Clk, signal Osc, and parameter P. Further, counter 402 is adapted to being started or enabled by enable signal en400, and to being reset by reset signal rst400.

Like delay circuit 203, delay circuit 403 is adapted to shifting the phase of clock signal Clk by a previously-defined time delay D. In the example illustrated in FIG. 4, delay circuit 403 comprises:
a first rising edge shift circuit 404 (Clk Gen Up);
a second falling edge shift circuit 405 (Clk Gen DW); and
an logic gate 406 (XOR) of EXCLUSIVE OR type, also called XOR gate.

According to a first embodiment, counter 402 is adapted to transmitting the number of periods of signal Osc which have been completed during a clock cycle Tolk and parameter P to delay circuit 403. According to a second embodiment, counter 402 is adapted to directly transmitting the result of the decision between the number of periods of signal Osc which have been completed during a clock cycle Telk and parameter P to delay circuit 403.

According to an example, the first rising edge shift circuit 404 is adapted to receiving: clock signal Clk;
reset signal rst400;
signal Osc;
an enable signal en402;
the signal representing parameter P, if applicable; and
a signal representing value cnt, if applicable.

The first circuit 404 is adapted to delivering, as an output, a first shifted signal Clkout_p400. The first circuit 404 is started by enable signal en402 generated by circuit 402 when the cnt value is set.

The first circuit 404 is adapted to shifting the rising edges of clock signal Clk by time delay D. For this purpose, the first circuit 404 uses parameter P and/or value cnt in combination with signal Osc to determine delay D. More specifically, at each rising edge of clock signal Clk, the first circuit 404 waits for the time of time delay D to modify the state of its output signal Clkout_p400.

According to an example, the second falling edge shifting circuit 405 is adapted to receive:
clock signal Clk;
reset signal rst400;
signal Osc;
an enable signal en402;
the signal representing parameter P, if applicable; and
a signal representing value cnt, if applicable.

Second circuit 405 is adapted to delivering as an output a second shifted signal Clkout_p400. The second circuit 405 is started by enable signal en40 en402 generated by circuit 402 when the cnt value is set.

Second circuit 405 is adapted to shifting the falling edges of clock signal Clk by time delay D. For this purpose, the second circuit 405 uses parameter P and/or value cnt in combination with signal Osc to determine delay D. More specifically, at each falling edge of clock signal Clk, the second circuit 405 waits for the time of time delay D to modify the state of its output signal Clkout_n400.

XOR gate 406 receives the two signals Clkout_p400 and Clkout_n400 as inputs and applies the logic “EXCLUSIVE OR” function to obtain as an output reception clock signal S_Clk.

FIG. 5 shows timing diagrams illustrating the time variation of signals of the circuit 400 described in relation with FIG. 4.

More specifically, FIG. 5 comprises:
a timing diagram 501 illustrating the time variation of clock signal Clk;
a timing diagram 502 illustrating the time variation of signal Osc;
a timing diagram 503 illustrating the time variation of the first shifted signal Clkout_p400;
a timing diagram 504 illustrating the time variation of the first shifted signal Clkout_n400; and
a timing diagram 505 illustrating the time variation of reception clock signal S_Clk.

As previously described, signal Osc has a period Tosc at least shorter than clock cycle Tclk divided by two. In the case illustrated in FIG. 5, period Tosc is equal to one eighth of clock cycle Tclk.

It is agreed that the value cnt determined by the counter is eight, and that delay D is given by the following mathematical formula:

$$D = Tosc * \frac{8}{2 * 2} = 2 * Tosc \qquad [ Math 4 ]$$

As previously described, signal Clkout_p400 changes state at each rising edge of clock signal Clk, being delayed by delay D, and signal Clkout_n400 changes state at each falling edge of clock signal Clk, being delayed by delay D. Signal S_Clk is equal to the combination by the XOR logic gate of signals Clkout_p400 and Clkout_n400.

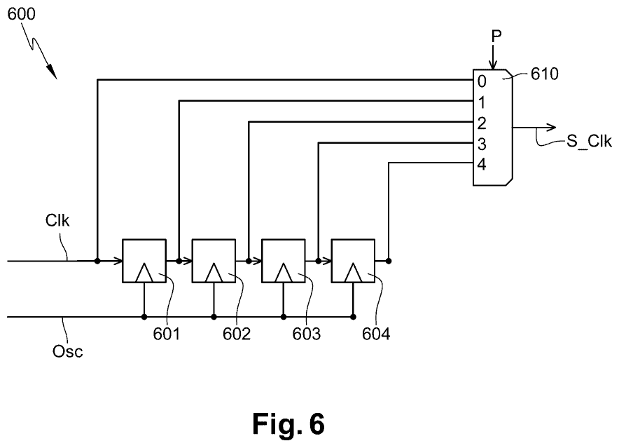

FIG. 6 shows another example of embodiment of a delay circuit 600 capable of being used like the delay circuit 203 described in relation with FIG. 2.

Like delay circuit 203, delay circuit 600 is adapted to receiving, as an input, clock signal Clk and periodic signal Osc, and to delivering as an output the new clock signal S_Clk. Circuit 600 is further adapted to receiving, as an input, the parameter P described in relation with FIG. 2.

Delay circuit 600 comprises flip-flops 601 to 604 and a selector 610. Delay circuit 600 is adapted to supplying a signal S_Clk delayed by from zero (0) to four (4) periods Tosc of signal Osc, according to the value of parameter P. It is within the ability of those skilled in the art to adapt circuit 600 to delay by a different number of periods Tosc.

Flip-flops 601 to 604 are all controlled by signal Osc. The input of flip-flop 601 is adapted to receiving the clock signal. Flip-flops 601 to 604 are connected in series. In other words:
the output of flip-flop 601 is coupled, preferably connected, to the input of flip-flop 602;
the output of flip-flop 602 is coupled, preferably connected, to the input of flip-flop 603; and
the output of flip-flop 603 is coupled, preferably connected, to the input of flip-flop 604.

Selector 610 is adapted to selecting, according to parameter P, from among clock signal Clk and the outputs of flip-flops 601 to 604. Thus, for this purpose, the selector comprises five inputs 0 to 4 and one output supplying signal S_Clk. More particularly:
input 0 is adapted to receiving clock signal Clk;
input 1 is coupled, preferably connected, to the output of flip-flop 601;
input 2 is coupled, preferably connected, to the output of flip-flop 602;
input 3 is coupled, preferably connected, to the output of flip-flop 603; and
input 4 is coupled, preferably connected, to the output of flip-flop 604.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove.

A method of generation (300) of a first clock signal (S_Clk) based on a second clock signal (Clk), the first and second clock signals (S_Clk, Clk) having a same first time period (Tclk), and based on a third periodic signal (Osc) having a second time period (Tosc) equal to said first time period (Tclk) divided by a first number (K) greater than or equal to two, said method may be summarized as including the following successive steps: counting a second number (Cnt) of full periods of said third signal completed during a full period of said second clock signal (Clk); and generating said first clock signal (S_Clk) by shifting the phase of said second clock signal (Clk) by a delay (D) equal to said second time period (Tosc) multiplied by a third number (P) in the range from zero to said second number (Cnt).

A circuit (200; 400) of generation of a first clock signal (S_Clk) based on a second clock signal (Clk), the first and second clock signals (S_Clk, Clk) having a same first time period (Tclk), said circuit is summarized as including: an oscillating circuit (201; 401) adapted to generating a third signal (Osc) having a second time period (Tosc) equal to said first time period (Tclk) divided by a first number (K) greater than or equal to two; a counter (202; 302) adapted to counting a second number (Cnt) of full periods of said third signal (Osc) completed during a full period of said second clock signal (Clk); and a delay circuit (203; 403) adapted to generating said first clock signal by shifting the phase of said second clock signal by a delay (D) equal to said second time period multiplied by a third number (P) in the range from zero to said second number (Cnt).

Said first number (K) is greater than or equal to four.

Said first number (K) is greater than or equal to eight.

Said third number (P) is equal to said second number (cnt) divided by a multiple of two.

Said third number (P) is equal to said second number (cnt) divided by a multiple of four.

The counting of said second number (cnt) is performed by calculating the overage of the number of full periods of said third signal (Osc) which are completed during a plurality of full periods of said second clock signal (Clk).

To shift the phase of said second clock signal (Clk), a fourth signal (Clkout_p400) changing state at each rising edge of said second clock signal (Clk) and being delayed by said delay (D), and a fifth signal (Clkout_n400) changing state at each falling edge of said second clock signal (Clk) and being delayed by said delay (D), are used.

To obtain said first signal (S_Clk), a logic gate of “EXCLUSIVE OR” type is applied to said fourth signal (Clkout_p400) and to said fifth signal (Clkout_n400).

The generation of said first clock signal (S_Clk) is implemented by a delay circuit (403) taking as input said third number (P).

An electronic device (101, 102) is summarized as including a circuit (200, 400).

Said circuit (200, 400) is included in a communication module (1011, 1021) of said device (101, 102).

A method of communication between a first electronic device (101, 102) and a second electronic device (102, 101) is implemented.

Said first clock signal (S_Clk) is used to synchronize data signals (Data101, data102, data 103, data104) received by said first device (101, 102).

The communication method uses the single data rate (SDR) protocol, the double data rate (DDR) protocol, or the quad data rate (QDR) protocol.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method, comprising:
generating a first clock signal based on a second clock signal, the first and second clock signals having a same first time period, and based on a third periodic signal having a second time period equal to the first time period divided by a first number greater than or equal to two, the generating the first clock signal including:
counting a second number of full periods of the third signal completed during a full period of the second clock signal; and
generating the first clock signal by shifting the phase of the second clock signal by a delay equal to the second time period multiplied by a third number in the range from zero to the second number, the generating the first clock signal occurring in a delay circuit including a first rising edge shift circuit and a second falling edge shift circuit.

2. The method according to claim 1, further comprising compensating for a jitter with a jitter correction circuit.

3. The method according to claim 1, wherein the first number is greater than or equal to four.

4. The method according to claim 3, wherein the first number is greater than or equal to eight.

5. The method according to claim 1, wherein the third number is equal to the second number divided by a multiple of two.

6. The method according to claim 5, wherein the third number is equal to the second number divided by a multiple of four.

7. The method according to claim 1, wherein the counting of the second number is performed by calculating the overage of the number of full periods of the third signal which are completed during a plurality of full periods of the second clock signal.

8. The method according to claim 1, wherein, to shift the phase of the second clock signal, a fourth signal changing state at each rising edge of the second clock signal and being delayed by the delay, and a fifth signal changing state at each falling edge of the second clock signal and being delayed by the delay, are used.

9. The method according to claim 8, wherein, to obtain the first signal, a logic gate of exclusive OR (XOR) type is applied to the fourth signal and to the fifth signal.

10. The method according to claim 1, wherein the generation of the first clock signal is implemented by a delay circuit taking as input the third number.

11. An electronic device, comprising:
an oscillating circuit adapted to generate an oscillating signal having a second time period equal to a first time period of a first and second clock signal divided by a first number at least equal to two;
a counter adapted to count a second number of full periods of the oscillating signal completed during a full period of the second clock signal; and
a delay circuit adapted to generate the first clock signal by shifting the phase of the second clock signal by a delay equal to the second time period multiplied by a third number in the range from zero to the second number, the delay circuit including a first logic gate configured to receive a first shifted clock signal and a second shifted clock signal.

12. The electronic device according to claim 11, wherein the oscillating circuit, the counter, and the delay circuit are included in a communication module of the device.

13. The electronic device according to claim 11, wherein the second clock signal has a frequency in the range of 50 MHz to 10 GHz.

14. The electronic device according to claim 13, wherein the second clock signal has a frequency in the range of 500 MHz and 2 GHz.

15. The electronic device according to claim 11, wherein the delay circuit includes a rising edge shift circuit and a falling edge shift circuit.

16. The electronic device according to claim 11, wherein the first logic gate is an exclusive OR (XOR) gate coupled between an output of the rising edge shift circuit and an output of the falling edge shift circuit.

17. A method, comprising:
communicating between a first electronic device and a second electronic device, the communicating including:
transmitting a plurality of data signals along a respective plurality of data transmission channels; and
generating a reception clock signal synchronized to each of the plurality of data signals, the generating the reception clock signal including:
generating a first clock signal based on a second clock signal, the first and second clock signals having a same first time period, and based on a third periodic signal having a second time period equal to the first time period divided by a first number at least equal to two.

18. The method according to claim 17, wherein the first clock signal is used to synchronize the plurality of data signals received by the first device.

19. The method according to claim 17, wherein the communicating uses a single data rate protocol.

20. The method according to claim 17, wherein the generating the first clock signal includes:
counting a second number of full periods of the third signal completed during a full period of the second clock signal; and
generating the first clock signal by shifting the phase of the second clock signal by a delay equal to the second time period multiplied by a third number in the range from zero to the second number.
